(19) United States
(12) Patent Application Publication
(10) Pub. No.: US 2026/0011599 A1
(43) Pub. Date: Jan. 8, 2026

(54) COMPONENT FOR SEMICONDUCTOR MANUFACTURING APPARATUS, AND MANUFACTURING METHOD THEREFOR

(71) Applicant: TOKAI CARBON KOREA CO., LTD, Gyeonggi-do (KR)

(72) Inventor: Ki Won KIM, Gyeonggi-do (KR)

(21) Appl. No.: 18/880,811

(22) PCT Filed: Jul. 4, 2022
(86) PCT No.: PCT/KR22/09578

§ 371 Date: Jan. 2, 2025

(51) Int. Cl. H01L 21/687; H01J 37/32

(52) U.S. Cl. CPC H01L 21/68735; H01J 37/32642; H01J 2237/334

(57) ABSTRACT

The present invention relates to a component for a semiconductor manufacturing apparatus, and a heat-resistant material, and the component for a semiconductor manufacturing apparatus, according to the present invention, has a level difference with a plurality of layers on a cross-section thereof, wherein the plurality of layers includes a first surface exposed to plasma and a second surface loaded on the semiconductor manufacturing apparatus.

### TECHNICAL FIELD

The present disclosure relates to a component for a semiconductor manufacturing apparatus and a method of manufacturing the same.

### BACKGROUND ART

In general, dry etching used in semiconductor manufacturing processes includes plasma etching using plasma and gaseous etching gas. This includes injecting etching gas into a reaction vessel, ionizing it, and accelerating it to a wafer surface to physically and chemically remove the top layer of the wafer surface, and is widely used because it is easy to control etching, high productivity is achieved, and a formation of a fine pattern of tens of nanometers (nm) is enabled.

When considering a wafer on which etching is actually performed, uniform application of a high frequency to ensure uniform energy distribution over the entire wafer surface is essential, and it is impossible to achieve applying of uniform energy distribution when such a high frequency is applied, by simply controlling an output of the high frequency, and to solve such an issue, it is largely determined by the shape of a stage and an anode as a high frequency electrode used to apply a high frequency to a wafer, and an edge ring that actually functions to fix the wafer. The edge ring functions to prevent a diffusion of plasma within a reaction chamber of a dry etching device under harsh conditions in which a plasma exists and confine the plasma around a wafer on which etching is performed.

In general, when materials are produced using chemical vapor deposition (CVD), a plurality of deposition layers may be stacked, however, processability decreases despite good plasma resistance in comparison to materials produced using a sintering method and including dense pores.

In particular, a complex shape due to a plurality of stepped portions has issues, such as a difficulty in precise processing, an increase in processing time, a decrease in productivity, and a rise in costs.

In addition, when boundaries of a plurality of deposition layers are exposed through processing, particles may be generated due to issues such as non-uniform plasma etching at a stack boundary.

Therefore, in a method of manufacturing a component, in particular, an edge ring, used in a plasma etching process in a semiconductor manufacturing process, a technology to minimize generation of particles and enhance processability of a product as it is used in a semiconductor process still needs to be developed as a core area to lower the production cost of semiconductor products.

### DISCLOSURE OF THE INVENTION

### Technical Goals

The present disclosure is to solve the above-described problems, and an aspect of the present disclosure is to provide a component for a semiconductor manufacturing apparatus and a method of manufacturing the same that may enhance productivity by minimizing a processing process requiring a large amount of time to manufacture a component of the semiconductor manufacturing equipment parts. In addition, another aspect of the present disclosure is to prevent a generation of particles by preventing a boundary surface from being exposed during a plasma etching process.

However, goals to be achieved by the present disclosure are not limited to those described above, and other goals not mentioned above can be clearly understood by one of ordinary skill in the art from the following description.

### Technical Solutions

A component for a semiconductor manufacturing apparatus of the present disclosure includes a step between a plurality of layers on a cross section of the component, and the plurality of layers includes a first surface exposed to a plasma and a second surface seated on the semiconductor manufacturing apparatus.

The first surface may be the same stack layer.

A plasma resistance of the first surface may be greater than a plasma resistance of the second surface, and the cross section may include laminate surfaces that are stacked and formed along the first surface.

The same layer of the plurality of layers may include grains with a size deviation of ±10% from an average value.

The first surface may be an inclined surface exposed to the plasma, and the second surface may be a base surface.

The first surface may be a chemical vapor deposition (CVD) substrate surface, and the second surface may be a CVD growth surface.

The component may be formed by a CVD growth from the first surface.

Grains of the same layer among the plurality of layers may have a size within ±10% of an average grain size.

A grain size of the first surface may be less than a grain size of the second surface. The component may be an edge ring, and the first surface may include a step and may be a wafer seating surface.

The component may be formed of a plasma-resistant material, for example, silicon carbide (SiC) or boron carbide (B4C).

The component may be a component in which a boundary of a deposition layer is non-exposed to a plasma.

A method of manufacturing a component for a semiconductor manufacturing apparatus includes: a step of preparing a base material: a step of forming a deposition layer including SiC or B4C to surround the base material: a step of processing the deposition layer; and a step of obtaining a component for a semiconductor manufacturing apparatus by removing the base material, the component including at least one SiC or B4C.

The base material may include a carbon-based material.

The deposition layer may be formed by a CVD growth from a first surface in contact with the base material to a second surface that is a target surface to be processed.

A plasma resistance of the first surface may be greater than a plasma resistance of the second surface.

The first surface may be an inclined surface exposed to a plasma, and the second surface may be a base surface.

A grain size of the first surface may be less than a grain size of the second surface.

The base material may have a vertically symmetrical shape, and the component including the at least one SiC or B4C may have the same shape.

The component may be an edge ring, and a top surface and a bottom surface of the base material may include steps.

### Effects of the Invention

A component for a semiconductor manufacturing apparatus according to an embodiment of the present disclosure may have an excellent plasma resistance as a surface exposed to a plasma is formed as the same surface despite lamination by a CVD, and accordingly it is possible to reduce an etching rate by the plasma. Therefore, a replacement period of the component for the semiconductor manufacturing apparatus may be increased by extending the life of the component for the semiconductor manufacturing apparatus, thereby reducing costs incurred by replacing the component for the semiconductor manufacturing apparatus.

In addition, since the replacement period of the component for the semiconductor manufacturing apparatus increases, an interruption of an etching process may be reduced, thereby enhancing a productivity of a semiconductor plasma etching process.

A method of manufacturing a component for a semiconductor manufacturing apparatus according to an embodiment of the present disclosure has an effect of ultimately reducing production costs of a semiconductor product due to an increase in processability by omitting a portion of a conventional processing process in a process of manufacturing a component for a semiconductor manufacturing apparatus. In addition, since a single process is performed to obtain at least one component for a semiconductor manufacturing apparatus, it may be expected that a manufacturing process may be shortened and a production efficiency of a component for a semiconductor manufacturing apparatus may be enhanced.

Furthermore, according to an embodiment of the present disclosure, since a boundary surface is not exposed during a plasma etching process, an effect of preventing a generation of particles may be obtained.

### BRIEF DESCRIPTION OF THE DRAWINGS

FIG. 1 is a cross-sectional view of a component for a semiconductor manufacturing apparatus according to an embodiment of the present disclosure.

FIG. 2 is a cross-sectional view illustrating an example of a stack surface of a component for a semiconductor manufacturing apparatus according to an embodiment of the present disclosure.

FIG. 3 is a cross-sectional view illustrating an example of a grain size of each of a first surface and a second surface according to an embodiment of the present disclosure.

FIGS. 4 to 7 are diagrams illustrating an example of a process of manufacturing a component for a semiconductor manufacturing apparatus according to an embodiment of the present disclosure.

FIGS. 8 to 11 are diagrams illustrating another example of a process of manufacturing a component for a semiconductor manufacturing apparatus according to an embodiment of the present disclosure.

### BEST MODE FOR CARRYING OUT THE INVENTION

Hereinafter, embodiments of the present disclosure will be described in detail with reference to the accompanying drawings. In the description of the present disclosure, detailed description of well-known related functions or configurations will be omitted when it is deemed that such description will cause ambiguous interpretation of the present disclosure. In addition, the terminologies used herein are for the purpose of appropriately describing embodiments of the present disclosure, and may vary depending on the intention of users or operators or customs in the art to which the present disclosure belongs. Therefore, terms used herein should be defined based on the content throughout the present specification. In the drawings, like reference numerals are used for like elements.

In the whole specification, when one member is positioned “on” another member, this not only includes a case in which the one member is brought into contact with the other member, but also includes a case in which another member exists between two members.

It will be understood throughout the whole specification that, when one part “includes” or “comprises” one component, the part does not exclude other components but may further include the other components.

Hereinafter, a component for a semiconductor manufacturing apparatus and a method of manufacturing the same according to the present disclosure will be described in detail with reference to embodiments and drawings. However, the present disclosure is not limited to the embodiments and drawings.

The component for the semiconductor manufacturing apparatus according to the present disclosure includes a step of a plurality of layers (between the plurality of layers) on a cross section of the component, and the plurality of layers includes a first surface exposed to a plasma and a second surface seated on the semiconductor manufacturing apparatus.

The component for the semiconductor manufacturing apparatus according to the present disclosure relates to one component of an apparatus for manufacturing a semiconductor, rather than a semiconductor itself. In other words, it relates to a component of a semiconductor manufacturing apparatus.

The component for the semiconductor manufacturing apparatus according to an embodiment of the present disclosure may reduce an etching rate indicating etching by a plasma, due to an excellent plasma resistance thereof. Thus, a replacement cost for the component for the semiconductor manufacturing apparatus may be reduced by extending the life of the component for the semiconductor manufacturing apparatus, and a productivity of an etching process may be enhanced by reducing an interruption of the etching process according to the component for the semiconductor manufacturing apparatus. In addition, according to the present disclosure, since a boundary surface is not exposed during a plasma etching process, a generation of particles may be prevented, thereby resolving a process-related issue caused by particles.

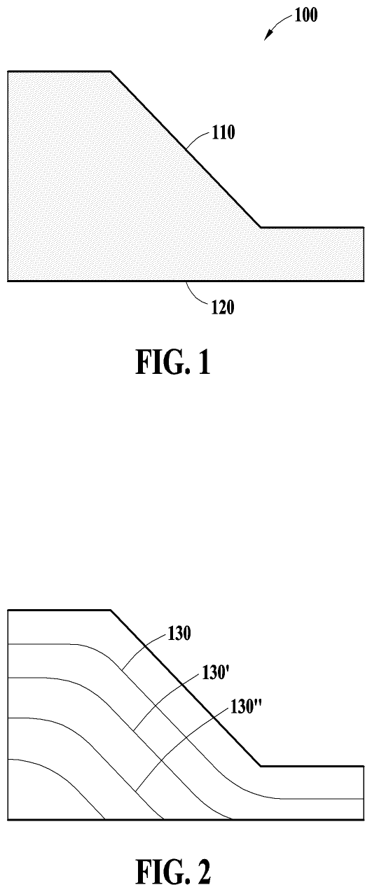

FIG. 1 is a cross-sectional view of a component for a semiconductor manufacturing apparatus according to an embodiment of the present disclosure.

Referring to FIG. 1, a component 100 according to an embodiment of the present disclosure includes a first surface 110 and a second surface 120.

According to an embodiment, the first surface 110 and the second surface 120 may differ from each other in plasma resistance of silicon carbide (SiC), and the above difference may cause a difference in an etching tendency for a plasma. Accordingly, the first surface 110 around a wafer, on which etching is performed in a reaction chamber of a semiconductor manufacturing apparatus under harsh conditions in which a plasma exists, for example, a dry etching device, has a greater plasma resistance than that of the second surface 120, which may extend the life of the component for the semiconductor manufacturing apparatus.

According to an embodiment, the first surface may be the same stack layer. When the first surface exposed to a plasma environment includes a boundary of a stack because the first surface is not the same stack layer (the same deposition surface), particles may be generated from the boundary of the stack. On the other hand, since the first surface exposed to a plasma environment is the same stack layer (the same deposition surface) in the component for the semiconductor manufacturing apparatus of the present disclosure, and the boundary of the stack is not included, a generation of particles or generation of a defect portion may be reduced, and thus, plasma resistance may be further enhanced.

The first surface 110 may be an inclined surface exposed to the plasma, and the second surface 120 may be a base surface. The inclined surface exposed to the plasma may be a surface on which the component 100 is mounted and that is exposed to a plasma generated in the semiconductor manufacturing apparatus. The base surface may be a surface on which the component 100 is grown by a chemical vapor deposition (CVD) and processed and mounted on a manufacturing device.

In particular, since the CVD process is used to form the component 100, the component 100 may have a sufficient corrosion resistance and strength and include a homogeneous surface without pores. In addition, the component 100 may be formed of a plasma resistant material, for example, silicon carbide (SiC) or boron carbide (B4C).

According to an embodiment, the first surface 110 may be an inclined surface exposed to the plasma, the second surface 120 may be a base surface, the first surface may be a CVD substrate surface, and the second surface may be a CVD growth surface.

The CVD substrate surface may be a surface on which a deposition of the component 100 by CVD is started. The CVD growth surface may be a surface on which a material is grown through the deposition of the component 100 by CVD.

According to an embodiment, the component 100 may be formed by a CVD growth from the first surface 110.

According to an embodiment, the first surface 110 may be a shapeless processed surface (that is not specifically shaped according to intention) on which processing is substantially not performed to change a shape. The shapeless processed surface may indicate that some processing such as planarization may be performed, but processing to actually change the shape may not be performed.

The first surface 110 may be a shapeless processed surface with a non-processed shape, as a surface on which a deposition by CVD is started, as a shapeless processed surface.

The plasma resistance of the first surface may be greater than the plasma resistance of the second surface, and the cross section may include stack layers stacked and formed along the first surface.

FIG. 2 is a cross-sectional view illustrating an example of a stack surface of a component for a semiconductor manufacturing apparatus according to an embodiment of the present disclosure.

Referring to FIG. 2, the component for the semiconductor manufacturing apparatus according to an embodiment of the present disclosure is formed by laminating SiC along the first surface 110, and boundaries 130, 130′, and 130″ between a plurality of stacks in a cross section show stack lines having a curved shape matching a shape of the first surface.

Each layer of a stack layer of the component for the semiconductor manufacturing apparatus may be stacked parallel to the stack surface of the component for the semiconductor manufacturing apparatus.

Referring to FIG. 2, since a plasma resistant surface includes the same deposition surface, it has uniform etching characteristics and a degree is also uniform. When a boundary at which different deposition surfaces meet is exposed, particles may be easily generated at a corresponding boundary portion due to a plasma, and when a corresponding point is relatively etched, continuous etching concentration may occur, which may trigger a decrease in all physical properties. However, in the present disclosure, since a plasma resistant surface does not include a deposition surface boundary, the above-described generation of particles and etching concentration and acceleration may be prevented.

The same deposition surface used herein refers to a deposition surface exhibiting the same degree of transmittance. The transmittance is a degree to which light passes through a material layer, and is a value obtained by dividing an intensity of light passing through the material layer by an intensity of light incident on the material layer. The transmittance may be measured in various ways, and measured, for example, at a distance between the specimen and the light source within 7 cm by preparing a specimen with a thickness of 3 mm and using a light source with an intensity of 150 Lux or higher.

A specimen with a thickness of 2 mm may be prepared, and the same deposition surface may be clearly confirmed when the prepared specimen with 2 mm is observed with a photograph and video. A specimen with a thickness of 1 mm may be prepared and the same deposition surface may be clearly confirmed when the specimen with the thickness of 1 mm is observed with the naked eye. Since the transmittance varies depending on the thickness, light source, and distance between the specimen and the light source, it may be taken into consideration as a relative value in the case of the same thickness.

According to an embodiment, the stack surface may include a curved surface.

According to an embodiment, the same layer of the plurality of layers may include grains having a size deviation of ±10% from an average value. The grain size may be an average diameter of grains. The grain size may gradually increase or be similar in a direction in which stack surfaces are stacked from the first surface 110 to the second surface 120.

According to an embodiment, the same layer of the plurality of layers may include grains with a size deviation of ±10% from an average value. According to an embodiment, a grain size of the first surface 110 may be less than a grain size of the second surface 120.

Since each layer is formed by the same deposition process, a surface of each layer may include grains with a size deviation of ±10% from the average value.

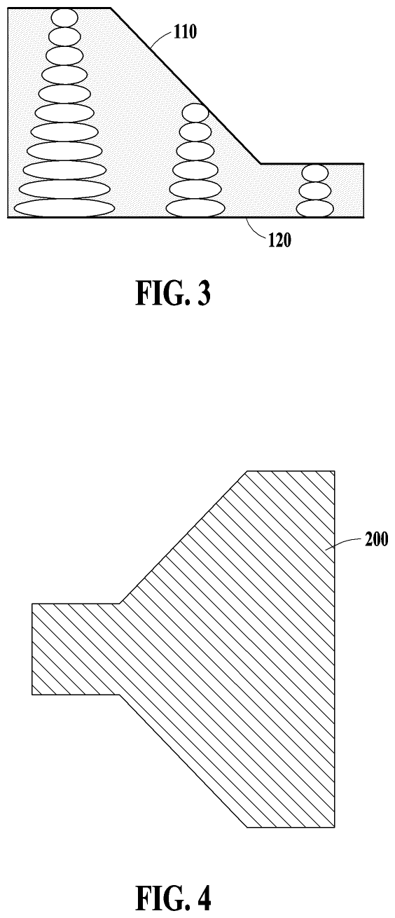

FIG. 3 is a cross-sectional view illustrating an example of a grain size of each of a first surface and a second surface according to an embodiment of the present disclosure.

Referring to FIG. 3, the grain size of the first surface 110 is relatively small and dense as the raw material is deposited by the CVD and the material of the component begins to grow, and as the deposition is performed, that is, as it goes toward the second surface 120, the grain size of SiC increases. Accordingly, the component 100 may be formed through repeating of a plurality of stack surfaces, and the same stack surfaces may have the same grain size.

In an embodiment, the first surface 110 and the second surface 120 may differ from each other in grain sizes of SiC, and the above difference may cause a difference in an etching tendency for a plasma. Since the first surface 110 has small and dense grain sizes of SiC around a wafer, on which etching is performed in a reaction chamber of a semiconductor manufacturing device, for example, a dry etching device, in comparison to the second surface 120, an etching rate indicating etching by a plasma may be reduced. In other words, as the grain size decreases, the plasma resistance may increase, and as the grain size increases, the plasma resistance may decrease.

According to an embodiment, the component for the semiconductor manufacturing apparatus may be an edge ring, and the first surface may include a step and be a wafer seating surface. The edge ring prevents a diffusion of a plasma while fixing a wafer in a reaction chamber of the semiconductor manufacturing apparatus, and allows the plasma to be concentrated around a wafer where an etching process is performed. By exposing the first surface 110 of the edge ring with a small grain size to the plasma, an etching rate at which the edge ring is etched by the plasma may be reduced. Accordingly, a replacement cost for the edge ring may be reduced by extending the life of the edge ring, and a productivity of the etching process may be enhanced by reducing an interruption of the etching process due to a replacement of the edge ring.

According to an embodiment, the component for the semiconductor manufacturing apparatus may be an electrode, in addition to the edge ring. The electrode may be used in a plasma etching device, may include a plurality of holes, and may function to evenly distribute etching gas supplied from the outside into the plasma etching device and supply it into the plasma etching device. The supplied etching gas is converted to a plasma on a lower side of the electrode to etch a specific thin film of a substrate. Accordingly, since a bottom surface of the electrode comes into contact with the plasma, an etching rate at which the electrode according to an embodiment of the present disclosure is etched by the plasma may be reduced when the electrode is used, thereby extending the life of the electrode.

The component may be formed of a plasma resistant material, for example, SiC or B4C, and according to an embodiment, the component for the semiconductor manufacturing apparatus may be used as a component, for example, an edge ring, an electrode, and various susceptors, applied to a formation of various components of a dry etching device for manufacturing of a semiconductor applied to an environment exposed to a plasma including SiC or B4C. In addition, the component may be a component in which a boundary of a deposition layer is not exposed to a plasma.

A method of manufacturing a component for a semiconductor manufacturing apparatus according to the present disclosure includes a step of preparing a base material; a step of forming a deposition layer including SiC or B4C to surround the base material; a step of processing the deposition layer; and a step of obtaining a component for a semiconductor manufacturing apparatus including at least one SiC or B4C by removing the base material.

In the method of manufacturing the component for the semiconductor manufacturing apparatus according to an embodiment of the present disclosure, a portion of a conventional processing process may be omitted in a process of manufacturing a component for a semiconductor manufacturing apparatus, thereby increasing a processability, to ultimately reduce the production cost of a semiconductor product. In addition, since a single process is performed to obtain at least one component for a semiconductor manufacturing apparatus, the manufacturing process may be shortened and an increase in a production efficiency of a component for a semiconductor manufacturing apparatus may be expected.

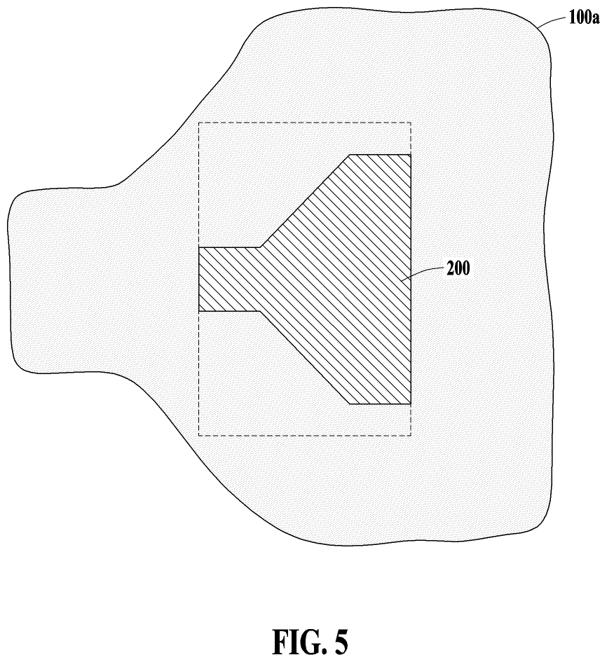

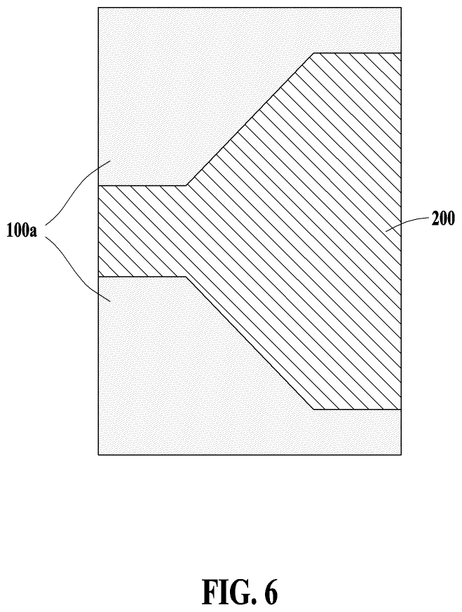

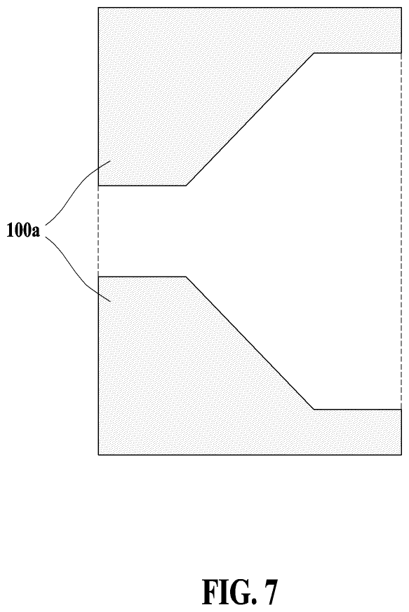

FIGS. 4 to 7 are diagrams illustrating an example of a process of manufacturing a component for a semiconductor manufacturing apparatus according to an embodiment of the present disclosure. Referring to FIGS. 4 to 7, the process of manufacturing the component for the semiconductor manufacturing apparatus according to an embodiment of the present disclosure includes a step of preparing a base material (FIG. 4), a step of forming a deposition layer (FIG. 5), a step of processing the deposition layer (FIG. 6), and a step of obtaining a component (FIG. 7).

Referring to FIG. 4, the step of preparing the base material is a step of preparing a base material 200.

According to an embodiment, the base material 200 may include a carbon-based material. The base material 200 may include, for example, graphite, carbon black, and the like. The base material may include, but is not limited to, for example, all carbon-based materials with surfaces on which a deposition material such as SiC or B4C is uniformly and properly deposited. Desirably, a material that may be easily separated from a deposition layer of a material such as SiC or B4C may be preferred.

According to an embodiment, a shape of the base material 200 is not particularly limited as long as a homogeneous deposition layer of a deposition material such as SiC or B4C may be formed on an upper portion and a lower portion thereof. However, when considering a structure of a deposition chamber in which a deposition material such as SiC or B4C may be deposited, a shape of the base material may be formed to have a shape of a ring to form a homogeneous deposition layer of a deposition material such as SiC or B4C on the base material.

Referring to FIG. 5, the step of forming the deposition layer may be a step of forming a SiC or B4C deposition layer 100a to surround the base material 200. A homogenous SiC or B4C deposition layer may be formed on a side surface of the base material 200 in addition to the upper portion and the lower portion of the base material 200.

According to an embodiment, if the deposition layer 100a includes SiC, raw material gas may be gas including at least one selected from a group consisting of CH₃SiCl₃, (CH₃)₂SiCl₂, (CH₃)₃SiCl, (CH₃)₄Si, and CH₃SiHCl₂, or gas including SiCl₄ gas including at least one selected from a group consisting of CH₄, C₃H₈, C₆H₁₄, C₇H₈, and CCl₄, and if the deposition layer 100a includes B4C, the raw material gas may include at least one selected from a group consisting of BCl₃, B₂H₆, BF₃, CH₄, C₂H₆, and C₃H₈.

According to an embodiment, in the step of forming the deposition layer, a deposition may be performed at a deposition temperature of 1000° C. to 1900° C. and a deposition rate of 20 μm/h to 400 μm/h.

According to an embodiment, if the deposition temperature in the step of forming the deposition layer is less than 1000° C., an amorphous phase may be included due to an very low temperature, which may rapidly reduce the plasma resistance, and a productivity issue may occur due to a low deposition layer formation speed. If the deposition temperature in the step of forming the deposition layer exceeds 1900° C., an issue with a deposition quality may occur, such as peeling in the deposition layer. If the deposition rate is less than 20 μm/hour, a productivity issue may occur due to a low deposition layer formation speed, and if the deposition rate exceeds 400 μm/hour, issues may occur such as a presence of pores between the base material and the deposition layer due to an excessively high speed, which may cause issues with homogeneous deposition.

According to an embodiment, the deposition layer may be formed by a chemical vapor deposition (CVD) growth from a first surface in contact with the base material to a second surface that is a target surface to be processed. The first surface and the second surface are the same as the first surface 110 and the second surface 120 shown in the cross-sectional view of the component 100 for the semiconductor manufacturing apparatus of FIG. 1. Since the SiC or B4C deposition layer is formed by the CVD, it has a homogeneous surface without pores. Thus, strength and corrosion resistance are excellent due to chemical properties of SiC and B4C and an etching rate for a plasma is low due to excellent surface homogeneity in a manufacturing method.

Referring to FIG. 6, in the step of processing the deposition layer 100a, the deposition layer may be processed to have a shape of a component to easily secure the SiC or B4C deposition layer 100a surrounding the base material 200 as a component for a semiconductor manufacturing apparatus.

Referring to FIG. 7, in the step of obtaining the component, a component 100 for a semiconductor manufacturing apparatus including at least one SiC or B4C may be obtained by removing the base material 200. After the SiC or B4C deposition layer surrounding the base material is processed, the base material and the component for the semiconductor manufacturing apparatus may be easily separated.

According to an embodiment, when the base material 200 is removed, one surface of the base material may be formed to correspond to the shape of the component, so that a SiC or B4C surface stacked on the base material and in contact with the base material may have a shape of one surface of the component, and thus, a processing process to change the shape may be omitted, thereby reducing the total number of processing processes. In other words, since a shape of a corresponding surface is determined in a process of deposition to a base material, the shape does not need to be changed by additional processing.

According to an embodiment, a plasma resistance of the first surface may be greater than a plasma resistance of the second surface. The first surface and the second surface may differ from each other in a plasma resistance of SiC or B4C, and the above difference may cause a difference in an etching tendency for a plasma. Accordingly, the first surface around a wafer, on which etching is performed in a reaction chamber of a semiconductor manufacturing apparatus under harsh conditions in which a plasma exists, for example, a dry etching device, has a greater plasma resistance than that of the second surface, which may extend the life of the component for the semiconductor manufacturing apparatus.

According to an embodiment, the first surface may be an inclined surface exposed to a plasma, and the second surface may be a base surface. The inclined surface exposed to the plasma, which is a surface on which a plasma generated in the semiconductor manufacturing apparatus is exposed, may be a surface around a surface on which a wafer, or the like is seated. The base surface may be a surface on which SiC or B4C is grown by a CVD and processed.

The first surface may be a CVD substrate surface, the second surface may be a CVD growth surface, and the component may be formed by a CVD growth from the first surface.

Grains of the same layer among stack surfaces may have a size within ±10% of an average grain size.

According to an embodiment, a grain size of the first surface may be less than a grain size of the second surface. The grain size of the first surface and the grain size of the second surface may be the same as those described above with reference to FIG. 2. The grain size of the first surface is relatively small and densely deposited as SiC or B4C begins to grow, and as deposition progresses, that is, as it moves toward the second surface, the grain size of SiC or B4C may increase. The first surface and the second surface differ from each other in the grain size of the SiC or B4C, which may cause a difference in an etching tendency for a plasma. Since the first surface has small and dense grain sizes of SiC or B4C around a wafer, on which etching is performed in a reaction chamber of a semiconductor manufacturing device, for example, a dry etching device, in comparison to the second surface, an etching rate indicating etching by a plasma may be reduced. In other words, as the grain size decreases, the plasma resistance may increase, and as the grain size increases, the plasma resistance may decrease.

According to an embodiment, the size of crystal grains may be measured using a Scherrer equation based on a full width at half maximum (FWHM) of a preferential growth peak in an X-ray diffraction analysis.

The FWHM may refer to a half width of the preferential growth peak shown in X-ray diffraction analysis, and the Scherrer equation may refer to an equation expressed by Equation 1.

$$Scherrer equation :$$

$$Size ( nm ) of crystal grains = 0.9 \times ( λ ( B \times cos θ ) ) \qquad [ Equation 1 ]$$

Here, λ denotes a measured wavelength of the X-ray diffraction analysis, B denotes the FWHM (rad) of the preferential growth peak, and θ denotes an angle value (rad) of the preferential growth peak.

According to an embodiment, the base material may have a vertically symmetrical shape, and the component for the semiconductor manufacturing apparatus including the at least one SiC or B4C may have the same shape. The base material may have a vertically symmetrical shape for a component for a semiconductor manufacturing apparatus to be obtained, and a component for a semiconductor manufacturing apparatus including at least one SiC or B4C may be formed after a SiC or B4C deposition layer surrounding the base material is processed.

According to an embodiment, a surface exposed by removing the base material in the component for the semiconductor manufacturing apparatus may not be processed. Since the surface exposed by removing the base material has an excellent plasma resistance due to a small grain size thereof, the surface exposed by removing the base material may be used instead of being processed.

According to an embodiment, in the step of processing the deposition layer, a surface of the deposition layer that is not in contact with the base material may be processed. Since the surface of the deposition layer that is not in contact with the base material has a large grain size, plasma resistance of the surface is relatively low in comparison to a surface with a small grain size, and thus the surface may be processed.

According to an embodiment, the component for the semiconductor manufacturing apparatus may be an edge ring, and a top surface and a bottom surface of the base material may include steps; and the component for the semiconductor manufacturing apparatus may be an edge ring, and the first surface may include a step and may be a wafer seating surface.

The component for the semiconductor manufacturing apparatus may be used as a component, for example, various electrodes and susceptors, as well as edge rings, applied to a formation of various components of a dry etching device for semiconductor manufacturing that is applied to an environment exposed to a plasma including SiC or B4C.

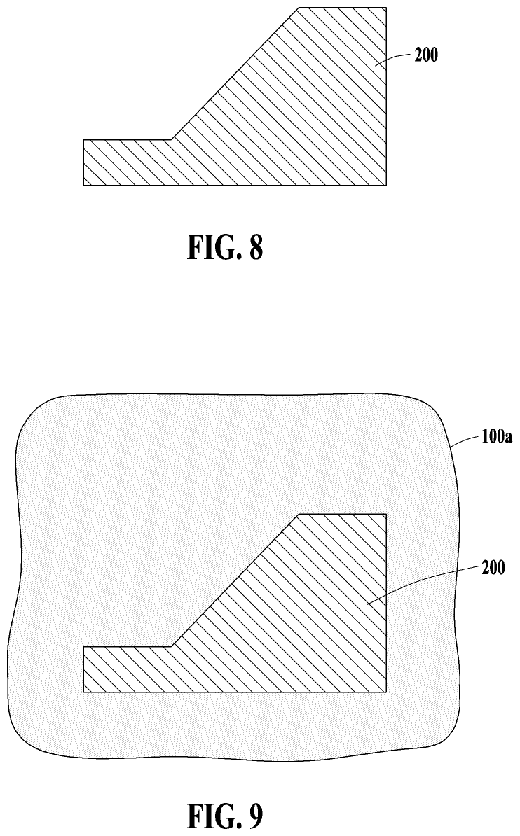

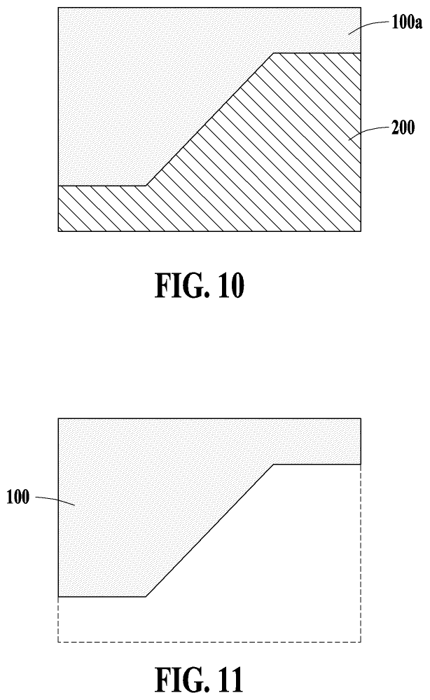

FIGS. 8 to 11 are diagrams illustrating another example of a process of manufacturing a component for a semiconductor manufacturing apparatus according to an embodiment of the present disclosure. Referring to FIGS. 8 to 11, the component for the semiconductor manufacturing apparatus of the present disclosure may be manufactured in the same manner using a base material that is not symmetrical. Since the base material is not disposed between two components as in FIGS. 4 to 7 although the same manner as that described with reference to FIGS. 4 to 7 is performed, it is impossible to obtain components from both sides based on the base material, however, an advantage that may be obtained by removing the base material and using a shapeless processed surface as an inclined surface exposed directly to a plasma is equally expected.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order and/or if components in a described system, architecture, device, or circuit are combined in a different manner and/or replaced or supplemented by other components or their equivalents. Therefore, other implementations, other embodiments, and equivalents to the claims are also within the scope of the following claims.

1. A component for a semiconductor manufacturing apparatus, the component comprising:
a step between a plurality of layers on a cross section of the component, wherein the plurality of layers comprises a first surface exposed to a plasma and a second surface seated on the semiconductor manufacturing apparatus.

2. The component of claim 1, wherein
the first surface is a same stack layer.

3. The component of claim 1, wherein
a plasma resistance of the first surface is greater than a plasma resistance of the second surface, and
the cross section comprises stack surfaces stacked and formed along the first surface.

4. The component of claim 1, wherein
a same layer of the plurality of layers comprises grains with a size deviation of ±10% from an average value.

5. The component of claim 1, wherein
the first surface is an inclined surface exposed to the plasma, and the second surface is a base surface.

6. The component of claim 1, wherein
the first surface is a chemical vapor deposition (CVD) substrate surface, and the second surface is a CVD growth surface.

7. The component of claim 1, wherein
the component is formed by a CVD growth from the first surface.

8. The component of claim 1, wherein
grains of a same layer among the plurality of layers have a size within ±10% of an average grain size.

9. The component of claim 1, wherein
a grain size of the first surface is less than a grain size of the second surface.

10. The component of claim 1, wherein
the component is an edge ring, and
the first surface comprises a step and is a wafer seating surface.

11. The component of claim 1, wherein
the component is formed of a plasma-resistant material, that is, silicon carbide (SiC) or boron carbide (B4C).

12. The component of claim 1, wherein
the component is a component in which a boundary of a deposition layer is non-exposed to a plasma.

13. A method of manufacturing a component for a semiconductor manufacturing apparatus, the method comprising:
a step of preparing a base material;
a step of forming a deposition layer comprising silicon carbide (SiC) or boron carbide (B4C) to surround the base material;
a step of processing the deposition layer; and
a step of obtaining a component for a semiconductor manufacturing apparatus by removing the base material, the component comprising at least one SiC or B4C.

14. The method of claim 13, wherein
the base material comprises a carbon-based material.

15. The method of claim 13, wherein
the deposition layer is formed by a CVD growth from a first surface in contact with the base material to a second surface that is a target surface to be processed.

16. The method of claim 15, wherein
a plasma resistance of the first surface is greater than a plasma resistance of the second surface.

17. The method of claim 15, wherein
the first surface is an inclined surface exposed to plasma, and the second surface is a base surface.

18. The method of claim 15, wherein
a grain size of the first surface is less than a grain size of the second surface.

19. The method of claim 13, wherein
the base material has a vertically symmetrical shape, and the component comprising the at least one SiC or B4C has a same shape.

20. The method of claim 13, wherein
the component is an edge ring, and
a top surface and a bottom surface of the base material comprise steps.
